(19) United States
(12) Patent Application Publication
(10) Pub. No.: US 2026/0219401 A1
(43) Pub. Date: Jul. 30, 2026

(54) SCINTILLATOR CRYSTALS, METHODS OF MANUFACTURE THEREOF AND ARTICLES COMPRISING THE SAME

(71) Applicant: Siemens Medical Solutions USA, Inc., Malvern, PA (US)

(72) Inventors: Mark Andreaco, Knoxville, TN (US); Peter Cohen, Knoxville, TN (US)

(21) Appl. No.: 19/158,243

(22) PCT Filed: May 31, 2023
(86) PCT No.: PCT/US2023/067659

§ 371 Date: Aug. 20, 2025

(51) Int. Cl. G01T 1/164; C09K 11/77; C30B 15/00; C30B 29/22; C30B 29/34; G01T 1/202

(52) U.S. Cl. CPC G01T 1/1642; C09K 11/77062; C30B 15/00; C30B 29/22; C30B 29/34; G01T 1/2023

(57) ABSTRACT

Disclosed herein is a rare earth oxyorthosilicate crystal having a formula (1): Lu_{2(1-a-b-c-d)}A₂ₐB_{2b}C_{2c}D_{2d}Si_{(1-x+y)}E_{y}O_{5(1-z)}, wherein Lu is lutetium; A comprises a trivalent ionic substitution selected from La, Ce, Pr, Nd, Sm, Eu, Gd, Tb, Dy, Ho, Er, Tm, Yb, Sc, Y, Al, Ga, B, In, Bi, Sb, Au, Rh, or a combination thereof; B comprises a non-trivalent ionic substitution selected from Mg, Ca, Sr, Ba, Li, Na, K, Rb, Mn, Cu, Zn, or a combination thereof; C comprises an activating cation substitution selected from Ce³⁺, Ce⁴⁺, Pr³⁺, or a combination thereof; D comprises a monovalent halogen anion substitution selected from F, Cl, Br, or a combination thereof; E comprises a trivalent ion substitution selected from La, Sc, Y, Al, Ga, In, B, In, Bi, Sb, Au, Rh, or any combination of thereof.

### BACKGROUND

This disclosure relates to scintillator crystals, methods of manufacture thereof and to articles comprising the same. In particular, this disclosure relates to scintillator materials used for detecting ionizing radiation in nuclear imaging applications particularly PET (Position Emission Tomography), TOF PET (Time of Flight Positron Emission Tomography) and/or DOI TOF PET (Depth of Interaction Time of Flight Positron Emission Tomography)) imaging.

Lutetium oxyorthosilicate (LSO), or Lu₂SiO₅ activated with cerium (Ce³⁺), is a well-known crystal scintillator material and widely used for medical imaging, such as gamma-ray detection in positron emission tomography (PET) as well as other applications. Due at least partly to its relatively high light yield and short decay time, LSO is considered to be one of the most suitable materials for molecular imaging applications specifically for time-of-flight PET (TOF PET).

LSO scintillators are typically made of single-crystal LSO grown from a melt using for example, Czochralski process. For scintillator applications, it is often desirable to be able to grow large single-crystals of LSO with specific scintillation performance parameters. The composition, size and quality of the grown crystals can be significantly affected by the growth stability.

While LSO scintillators of different dopant and co-dopants schemes have been well developed, efforts are on-going to develop rare earth oxyorthosilicate scintillators with selected isovalent and aliovalent substitutions of different concentrations to improve scintillation properties for specific applications.

### SUMMARY

Rare earth oxyorthosilicate scintillators are commonly used in medical diagnostic applications, in particular in time-of-flight positron emission tomography.

Selective changing of the mole ratios of multivalent substitution ions in scintillating compositions of rare earth oxyorthosilicate crystals enables the resulting crystals to display significant increase in scintillation light output, improvement in energy resolution, coincidence time resolution, scintillation rise time and decay time characteristics of the material, as compared with compositions activated only with cerium and/or praseodymium without the multivalent substitutions. Multivalent ions can be incorporated in the crystal lattice in relatively low concentrations, usually at commonly used doping and co-doping levels (below 1 atomic percent). Such substitutions can lead to the change of Ce³⁻ and Ce⁴⁻ concentration ratio along with stabilization of Ce⁴⁺ in crystallographic lattice for improvement in scintillation performance. Multivalent ions can also, be incorporated in much higher concentrations where they become an integral constituent of the modified scintillator host lattice with different translational symmetry. By selection of certain molar concentration ratios of multivalent ions it is possible to control the size of crystallographic lattice cell and in some cases its distortion, affecting segregation from the melt of certain ions during crystal growth process, as well as to modify charge state of these ions, and their locations in crystallographic sites.

The performance of rare earth oxyorthosilicate compositions described in this invention disclosure provide a significant improvement in coincidence time resolution of time-of-flight of PET systems.

Disclosed herein is a rare earth oxyorthosilicate crystal having a formula (1)

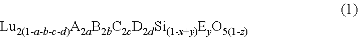

wherein Lu is lutetium; A comprises a trivalent ionic species selected from La, Ce, Pr, Nd, Sm, Eu, Gd, Tb, Dy, Ho, Er, Tm, Yb, Sc, Y, Al, Ga, B, In, Bi, Sb, Au, Rh, or a combination thereof; B comprises a non-trivalent ionic species selected from Mg, Ca, Sr, Ba, Li, Na, K, Rb, Mn, Cu, Zn, or a combination thereof; C comprises an activating cation selected from Ce³⁺, Ce⁴⁺, Pr³⁻, or a combination thereof; D comprises a monovalent halogen anion selected from F, Cl, Br, or a combination thereof; E comprises a trivalent ion selected from La, Sc, Y, Gd, Al, Ga, In, B, In, Bi, Sb, Au, Rh, or any combination of thereof; a is present in an amount of 0.5≤a≥0; b is present in an amount of 0.5≤b≥0; c is present in an amount of 0.5≤c≥0.00001; d is present in an amount of 0.5≤d≥0; x is present in an amount of 0.05≤x≥0; y is present in the amount 0.05≤y≥0; z is present in an amount of 0.2≤z≥0; where the sum of a+b is always greater than 0; and where the sum of a+b+c+d is always less than 1; and wherein A and C cannot simultaneously be identical trivalent cations.

Disclosed herein too is a method of manufacturing a rare earth oxyorthosilicate crystal comprising manufacturing a powder having a composition of formula (1):

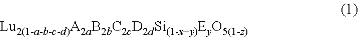

wherein Lu is lutetium; A comprises a trivalent ionic species selected from La, Ce, Pr, Nd, Sm, Eu, Gd, Tb, Dy, Ho, Er, Tm, Yb, Sc, Y, Al, Ga, B, In, Bi, Sb, Au, Rh, or a combination thereof; B comprises a non-trivalent ionic species selected from Mg, Ca, Sr, Ba, Li, Na, K, Rb, Mn, Cu, Zn, or a combination thereof; C comprises an activating cation selected from Ce³⁺, Ce⁴⁺, Pr³⁻, or a combination thereof; D comprises a monovalent halogen anion selected from F, Cl, Br, or a combination thereof; E comprises a trivalent ion selected from La, Sc, Y, Gd, Al, Ga, In, B, In, Bi, Sb, Au, Rh, or any combination of thereof; a is present in an amount of 0.5≤a≥0; b is present in an amount of 0.5≤b≥0; c is present in an amount of 0.5≤c≥0.00001; d is present in an amount of 0.5≤d≥0; x is present in an amount of 0.05≤x≥0; y is present in the amount 0.05≤y≥0; z is present in an amount of 0.2≤z≥0; where the sum of a+b is always greater than 0; and where the sum of a+b+c+d is always less than 1; and wherein A and C cannot simultaneously be identical trivalent cations; melting the powder in a crucible at a temperature of from 1500° C. to 2300° C.; and pulling the crystal from the melt using Czochralski technique or similar.

### BRIEF DESCRIPTION OF THE FIGURES

FIG. 1 is a graph that depicts afterglow for samples A B, C and a LSO reference;

FIG. 2 is a graph that depicts energy spectra of different compositions A, B, C and the LSO reference;

FIG. 3 depicts the coincidence resolving time for the samples A, B, C and the LSO reference;

FIG. 4 shows that the relative concentration of oxygen vacancies (thermoluminescence peaks above 300 k) is significantly reduced in the case of sample A in comparison to sample D (standard reference);

FIG. 5 depicts the thermal response of the samples A-D;

FIG. 6 depicts the radioluminescence of the selected samples A-D; and

FIG. 7 depicts spectra of Ce³⁺, Ce⁴⁺ optical absorption of the selected samples A-D.

### DETAILED DESCRIPTION

### Definitions

The rise time is the time interval during which the amplitude rises from 10% of the maximum to 90% of the light pulse following the absorption of the gamma photon.

Scintillation light pulses (flashes) are usually characterized by a fast increase of the intensity in time (pulse rise time) followed by an exponential or multiexponential decrease. The decay time of a scintillator is defined by the time after which the intensity of the light pulse has returned to 1/e of its maximum value.

The light output (number of photons per MeV of gamma energy absorbed in a scintillator) of most scintillators is a function of temperature. This is caused by the fact that in scintillation crystals, radiative transitions, responsible for the production of scintillation light, compete with nonradiative transitions (no light production).

Coincidence time resolution (CTR) and coincidence resolving time (CRT) are exchangeable terms commonly used in positron emission tomography.

Disclosed herein are rare earth oxyorthosilicate scintillator compositions (hereinafter scintillator compositions) which contain ratios of trivalent, divalent and monovalent ions which are incorporated in the crystal lattice as isovalent and aliovalent substitutions that permit the resulting scintillator single crystals to display a significant increase in scintillation light output, improvement in energy resolution, timing resolution, decay time and rise time characteristics when compared with compositions activated with only cerium and/or praseodymium without the multivalent substitutions.

Multivalent ions can be incorporated in the crystal lattice in relatively low concentrations, usually at commonly used doping and co-doping levels (below 1 at %). Several outcomes of such substitutions can lead to the change of Ce³⁻ and Ce⁴⁻ concentration ratios along with stabilization of Ce⁴⁺ in crystallographic lattice for improvement in scintillation performance. Further outcomes of such substitutions can lead to changes in relative populations of Ce1 and Ce2 crystallographic sites. Multivalent ions can also be incorporated in much higher concentrations where they become an integral constituent of the modified scintillator host lattice with different translational symmetry.

By selecting certain molar concentration ratios for the multivalent ions in the rare earth oxyorthosilicates it is possible to control the size of crystallographic lattice cell and in some cases its distortion, affecting segregation from the melt of certain ions during crystal growth process, as well as to modify charge state of these ions, and their locations in crystallographic sites. The performance of rare earth oxyorthosilicate compositions described in this disclosure provide a significant improvement in coincidence time resolution for time-of-flight PET systems. This disclosure relates particularly to control of decay time, rise time and scintillation light yield and coincidence time resolution of rare earth oxyorthosilicates.

The current invention applies to rare earth oxyorthosilicate crystals production process by growing from the melt using Czochralski method or other similar methods, some of which are detailed later. Melt composition includes the addition of carefully selected molar ratios of multivalent ions. These ratios are calculated in relation to molar concentration of activator co-dopants such as cerium and/or praseodymium. The composition of the melt and growth process control parameters have direct effect on thermodynamics of crystal growth process, changing Marangoni flow, and thermal convection, evaporative loses and thermal decompositions of the melt at different stages of the growth process. As a result, stoichiometry of the grown crystal can be significantly different from the composition of the original melt.

By addition to the melt of certain isovalent and aliovalent cations and anions based on their ionic radii and electron charge states, it is possible to modify crystallographic lattice symmetry of resulting crystals. These modifications stretch or contract crystallographic lattice sites disturbing periodic symmetry of the crystals. Presence of these modified lattice sites affects incorporation of dopants and co-dopants in their direct vicinity. Ionic radii can affect the segregation from the melt of certain dopants and co-dopants in the lattice. It is then possible to favorably increase concentration of certain dopants and co-dopants affecting scintillation performance of the material and limit concentration of the others, intended only to change thermodynamics of the crystallization process.

The selection of preferred isovalent and aliovalent ions at predetermined relative concentration ratios results in:
Changes in the concentration of ions built into the crystal lattice during crystal growth process,
Changes distributions of trivalent and divalent ions between different crystallographic sites of the rare earth site, oxyorthosilicate crystal site, as well as in the interstitial positions compensating for oxygen vacancy defects,
Changes relative spatial distribution of trivalent and divalent ions, creating certain predetermined clusters of divalent, trivalent and activator ions,
Affecting electron charge states of ions incorporated in the rare earth oxyorthosilicate lattice, specifically charge state ratio of cerium 3+ and 4+ in both crystallographic sites Ce1 and Ce2.
Controlling cerium ions population of both cerium crystallographic sites Ce1 and Ce2.

There is statistical probability in the thermodynamics of the growth process leading to deficiencies of specific ions and resulting charge state imbalance of defects in the lattice governing incorporation of selected ions substitutions favoring certain crystallographic sites, which could be a rare earth site, an oxyorthosilicate site or an interstitial site to restore charge balance in the lattice.

Single valence elements of trivalent cations such as: La³⁺, Ce³⁺, Pr³⁺, Nd³⁺, Sm³⁺, Eu³⁺, Gd³⁺, Tb³⁺, Dy³⁺, Ho³⁺, Er³⁺, Tm³⁺, Yb³⁺, Lu³⁺, Sc³⁺, Y³⁻ can primarily substitute for rare earth constituents of the rare earth oxyorthosilicate lattice. B³⁺, Al³⁺, In³⁺, Ga³⁺, Sb³⁺, Au³⁺, Bi³⁻, Rh³⁺ can primarily substitute for Si⁴⁺ in orthosilicate SiO⁴⁻ ion complexes deficient in the lattice of rare earth oxyorthosilicates. These deficiencies can be a result of loss of stoichiometry (that may be due to deliberate composition selection), selection of growth process parameters, or evaporative and decomposition losses during growth process.

Single valence elements of divalent cations such as: Be²⁺, Mg²⁺, Ca²⁺, Sr²⁺, Ba²⁺, Zn²⁺, Cd²⁻, Ni³⁺ can substitute to compensate for rare earth oxyorthosilicate oxygen vacancies generated during the growth process.

Anions such as: F⁻¹, Cl⁻¹, Br⁻¹, O⁻² can be added indirectly as a commercial chemical variants compounds of Ce³⁺ or Ce⁴⁺ activators. These are typically available commercially as cerium (IV) fluoride, CeF₄, cerium (III) chloride (CeCl₃), cerium (III) bromide (CeBr₃), cerium (IV) oxide (CeO₂), cerium (III) oxide (Ce₂O₃), or a combination thereof.

Single valence elements of trivalent cations mentioned above include La³⁺, Ce³⁺, Pr³⁺, Nd³⁺, Sm³⁺, Eu³⁺, Gd³⁺, Tb³⁺, Dy³⁺, Ho³⁻, Er³⁺, Tm³⁻, Yb³⁻, Lu³⁺, Sc³⁺, Y³⁺, or a combination thereof can be incorporated in the lattice at higher concentrations and can stretch or contract crystallographic lattice of rare earth oxyorthosilicate lattice cells. Cerium activator added to the melt can be incorporated into the lattice in the vicinity of these ions. As a result, the surrounding of the cerium may create favorable conditions for cerium to change its charge state from 3+ to 4+. Cerium in 4+ state enables a faster decay time and rise time in the scintillation emission. Divalent ions such as: Mg²⁺, Ca²⁻ and Sr²⁺ can be also incorporated in certain lattice locations based on their ionic radii. They can favorably modify scintillation performance of the rare earth oxyorthosilicate scintillators by changing populations of two the crystallographic sites of Ce³⁺ in oxyorthosilicate lattice. One of these sites produces fast scintillation emissions with decay time below 40 nanoseconds (ns) the other slow above 40 ns. Another outcome of these substitutions is charge state compensation.

Addition of SiO₂ in certain concentrations can be used to compensate for incongruency of the melt taking place in the oxygen depleted environment during crystal growth. SiO₂ is incorporated in the lattice as orthosilicate anion SiO⁴⁻. Rare earth oxyorthosilicate melt can partially decompose at high temperatures and oxygen deficient atmosphere due to volatility of SiO/SiO₂ evaporative losses. Oxygen deficiency in the melt from the decomposition of the melt constituents can create thermally reversable defects such as oxygen vacancies in a resulting crystal lattice. These can be compensated for during growth and post growth processes through the controlled addition of oxygen at elevated temperatures as well as the incorporation of divalent ions such as those mentioned earlier (e.g., Mg²⁺, Ca²⁺, Sr²⁺ or Ba³⁺) to the lattice.

Use of Y³⁺, Gd³⁺, Al³⁺, Ga³⁺, In³⁺ or B³⁺ and other trivalent cations listed above in selected concentration ratios in relation to concentration of cerium activator can compensate for losses of Si⁴⁻ and O²⁻ of SiO⁴⁻ complex site. The selected trivalent cations replace Si⁴⁺ and creates a charge state imbalance. Electron transfer from Ce³⁺ to the complex results in a stable Ce⁴⁺ state and restores charge balance.

In an embodiment, the scintillating composition includes a rare earth oxyorthosilicate described by the general chemical formula (1)

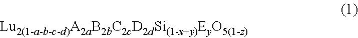

wherein Lu is lutetium; A comprises a trivalent ionic species (substitution) that comprises a rare earth metal selected from La, Ce, Pr, Nd, Sm, Eu, Gd, Tb, Dy, Ho, Er, Tm, Yb, Sc, Y, Al, Ga, B, In, Bi, Sb, Au, Rh, or a combination thereof; B comprises a non-trivalent (e.g., monovalent or divalent) ionic species (substitution) selected from Mg, Ca, Sr, Ba, Li, Na, K, Rb, Mn, Cu, Zn, or a combination thereof; C comprises trivalent dopant (activation) cation substitution such as Ce³⁺, Ce⁴⁺, Pr³⁺ ions, or a combination thereof; D comprises a monovalent halogen anion; E comprises an element selected from La, Sc, Y, Gd, Al, Ga, In, B, In, Bi, Sb, Au, Rh, or a combination thereof; a is present in an amount of 0.5≤a≥0; b is present in an amount of 0.5≤b≥0; c is present in an amount of 0.5≤c≥0.00001; d is present in an amount of 0.5≤d≥0; x is present in an amount of 0.05≤x≥0; y is present in the amount 0.05≤y≥0; z is present in an amount of 0.2≤z≥0; where the sum of a+b is always greater than 0; and where the sum of a+b−c+d is always less than 1. In an embodiment, the values of each of c, b, c and dare not simultaneously equal to 0.25 or greater and the maximum value of the sum of a+b+c+d ranges between 0.00001 to 0.4, preferably 0.00015 to 0.35; and x≥y. In an embodiment, the ratio of b:c in formula (1) may be from 1:1 to 10:1, preferably 2:1 to 5:1, while the ratio of a:c in formula (1) may be from 2.5:1 to 15:1, preferably 4:1 to 10:1.

In formula (1), the term “x” represents silica loss and is always greater than “y”, where y represents the substitution by element E. The term “z” represents the oxygen loss during manufacturing and implies the presence of oxygen vacancies in the crystal.

In an embodiment in formula (1), Lu is lutetium; A comprises a trivalent ionic substitution selected from La, Ce, Pr, Nd, Sm, Eu, Gd, Tb, Dy, Ho, Er, Tm, Yb, Sc, Y, Al, Ga, B, In, Bi, Sb, Au, Rh, or a combination thereof; B comprises a non-trivalent ionic substitution selected from Mg, Ca, Sr, Ba, Li, Na, K, Rb, Mn, Cu, Zn, or a combination thereof; C comprises an activating cation substitution selected from Ce³⁻, Ce⁴⁺, Pr³⁺, or a combination thereof; D comprises a monovalent halogen anion substitution selected from F, Cl, Br, or a combination thereof; E comprises a trivalent ion substitution (for silica) selected from La, Sc, Y, Gd, Al, Ga, In, B, In, Bi, Sb, Au, Rh, or any combination of thereof; a is present in an amount of 0.5≤a≥0; b is present in an amount of 0.5≤b≥0; c is present in an amount of 0.5≤c≥0.00001; d is present in an amount of 0.5≤d≥0; x is present in an amount of 0.05≤x≥0; y is present in the amount 0.05≤y≥0; z is present in an amount of 0.2≤z≥0; where the sum of a+b is always greater than 0; and where the sum of a|b|c|d is always less than 1; and wherein A and C cannot simultaneously be identical trivalent cations. In an embodiment, A, C and E cannot simultaneously be identical trivalent cations. In another embodiment, a content of ionic substitution E (for Si) is defined by x≥y.

In an embodiment, the rare earth oxyorthosilicate is a single crystal. In some embodiments, A is a trivalent cation of La, Ce, Pr, Nd, Sm, Eu, Gd, Tb, Dy, Ho, Er, Tm, Yb, Sc, Y, Al, Ga, B, In, Bi, Sb, Au, Rh, or a combination thereof; B is a non-trivalent cation (e.g., a monovalent or divalent cation) of Mg, Ca, Sr, Ba, Na, K, Rb, Mn, Cu, Zn, or a combination thereof; C is Ce³⁺, Ce⁴⁺, Pr³⁺, or a combination thereof; while D is a monovalent halogen anion such as, for example, F, Cl, Br, or a combination thereof.

In an embodiment, A and C cannot simultaneously be the same trivalent cation. For example, if A is a trivalent cation of Ce (e.g., Ce³⁺), then C will be either a tetravalent cation of Ce (e.g., Ce⁴⁺) or a trivalent cation of Pr (e.g., Pr³⁺). In some embodiments, a is an amount of 0.000001 to 0.25, preferably 0.001 to 0.2, preferably 0.01 to 0.15, preferably 0.05 to 0.1. In some embodiments, b is an amount of 0.000001 to 0.25, preferably 0.001 to 0.2, preferably 0.01 to 0.15, preferably 0.05 to 0.1. In some embodiments, c is an amount of 0.00002 to 0.35, preferably 0.001 to 0.3, preferably 0.002 to 0.2, preferably 0.01 to 0.15, preferably 0.05 to 0.1. In some embodiments, dis an amount of 0.00002 to 0.35, preferably 0.001 to 0.3, preferably 0.002 to 0.2, preferably 0.01 to 0.15, preferably 0.05 to 0.1. In some embodiments, x is an amount of 0.00002 to 0.05, preferably 0.001 to 0.05, preferably 0.002 to 0.04, preferably 0.01 to 0.03, preferably 0.02 to 0.025. In some embodiments, y is an amount of 0.00002 to 0.05, preferably 0.001 to 0.04, preferably 0.002 to 0.03, preferably 0.01 to 0.025 preferably 0.015 to 0.025. In some embodiments, z is an amount of 0.00002 to 0.05, preferably 0.001 to 0.04, preferably 0.002 to 0.03, preferably 0.01 to 0.025 preferably 0.015 to 0.025.

In some embodiments, the addition of trivalent ions (that are not the activating cation C) such as La³⁺, Nd³⁺, Sm³⁺, Eu³⁺, Gd³⁺, Tb³⁺, Dy³⁺, Ho³⁺, Er³⁺, Tm³⁻, Yb³⁺, Sc³⁺, Y³⁻, Al³⁺, Ga³⁺, B³⁺, In³⁺, Bi³⁻, Rh³⁺, Au³⁺, Sb³⁺, or a combination thereof, are incorporated in a crystal lattice at higher concentrations and can stretch or contract crystallographic lattice cells as described above. In other words, trivalent ions that are not the activating cation C cause a dimensional change in a crystallographic lattice cell. As a result, the surrounding of the cerium may create favorable conditions for cerium to change its charge state from 3+ to 4+ and this has a positive effect on scintillation performance of the crystal. In other words, the activating cation C changes its charge state from 3+ to 4+ when its nearest neighbor is one of the trivalent ionic species A (e.g., the trivalent cation A) or the non-trivalent ionic species B (e.g., the monovalent or divalent cation B).

Cerium in its 4+ state enables a faster decay time component of the scintillation emission. Divalent ions such as: Mg²⁺, Ca²⁻, Sr²⁺ and Ba²⁺ can be incorporated in certain lattice location based on their ionic radii. They can favorably modify scintillation performance of the rare earth oxyorthosilicate scintillators by changing populations of two the crystallographic sites of Ce³⁺ in rare earth oxyorthosilicate lattice. One of these sites produces fast scintillation emissions with decay time below 40 nanoseconds (ns) the other slow above 40 ns.

In an embodiment, the mole ratio of trivalent cations A (in formula (1)) to the activating ions C is greater than 0.1:1, preferably greater than 2:1, preferably greater than 4:1, preferably greater than 5:1, preferably greater than 8:1 and more preferably greater than 10:1. As noted above, A and C cannot simultaneously be the same trivalent cation.

In another embodiment, the mole ratio of non-trivalent (e.g., monovalent or divalent) cations B to the activating cations C (in formula (1)) is greater than 1:1, preferably greater than 1.5:1, preferably greater than or equal to 2:1, preferably greater than or equal to 3:1, preferably greater than or equal to 4:1, and more preferably greater than or equal to 5:1. In an embodiment, it may be desirable to simultaneously incorporate at least one trivalent cation A (in addition to the activating trivalent or tetravalent cation C) and at least two different monovalent or divalent cations in the crystal lattice.

In a preferred embodiment, it may be desirable to simultaneously incorporate at least one trivalent cation A (selected from La³⁺, Pr³⁺, Ce³⁺, Nd³⁺, Sm³⁺, Eu³⁺, Gd³⁺, Tb³⁺, Dy³⁺, Ho³⁺, Er³⁺, Tm³⁺, Yb³⁺, Sc³⁺, Y³⁺, Al³⁺, Ga³⁺, B³⁺, In³⁺, Bi³⁺, Au³⁺, Sb³⁺, Rh³⁺ or a combination thereof) in a mole ratio of at least 1:1, preferably at least 5:1, and more preferably at least 10:1 with respect to the activating cation C (selected from Ce³⁺, Ce⁴⁺, Pr³⁺ ions, or any combination thereof) while incorporating at least two cations (selected from Mg²⁻, Ca²⁺, Sr²⁺, Ba²⁺, Na¹⁻, K¹⁻, Rb¹⁺, Mn²⁺, Mn⁴⁺, Mn⁴⁺, Cu²⁺, Cu¹⁺, Zn²⁺, or a combination thereof) each in a mole ratio of at least 2:1 with respect to the activating cation C.

In an embodiment, the trivalent ion substitution A and the divalent ion substitution B change cerium doped rare earth oxyorthosilicate cerium ion distribution to predominantly occupy a Ce1 crystallographic site. In another embodiment, the trivalent ion substitution A and the divalent ion substitution B change cerium doped rare earth oxyorthosilicate cerium ion to a predominantly Ce⁴⁺ charge state.

In an embodiment, in one method of manufacturing the single crystal, powders of the raw materials are taken in a crucible and heated using induction heating. The powders have an average particle size that range from 5 nanometers to 500 micrometers, preferably 10 nanometers to 50 micrometers, and more preferably 1 to 20 micrometers. The radius of gyration of the particles is measured to determine average particle size. Light scattering or electron microscopy can be used to determine the particle size.

In an embodiment, nanometer and/or micrometer-sized particles may be manufactured separately (or purchased separately) and blended together to form the composition of formula (1) above. For example, nanometer and/or micrometer-sized powders of the rare earth oxyorthosilicate can be blended together in the desired stoichiometric quantities along with other particles (e.g., metal oxide particles, dopant particles) to form an intimate mixture. The intimate mixture is then heated to the elevated temperatures detailed below to form a single crystal. In other words, nanometer and/or micrometer-sized metal oxide powders of Lu, A, B, C, and silica (from formula (1) may be blended together along with halides of C (if desired) to produce an intimate mixture that is then heated as detailed below to form the single crystal.

In an embodiment, nanometer or micrometer-sized powders of lutetium oxide are added to a blender or mixer in the stoichiometric ratios detailed above. Nanometer or micrometer-sized metal oxide powders or metal salts (—e.g., oxides or salts of Lu, A and B) are added to the blender or mixer in the stoichiometric quantities listed above. Nanometer or micrometer-sized silica may also be added to the blender or mixer. The activating cation C (also called a dopant) (also in nanometer or micrometer-sized particles) may be added to the blender or mixer in the form of a salt (e.g., in the form of a metal halide) or as a metal oxide. Other reactants listed above may also be added to the blender or mixer. The powders thus added to the blender or mixer are subjected to blending to form an intimate mixture.

The powders obtained from the intimate mixture can be initially mixed and optionally further pulverized by milling them. The pulverized powders can then be subjected to an optional sieving process if it is desirable to use particles of a particular size.

The powders to make rare earth oxyorthosilicate are then melted at temperatures of 1500° C. to 2300° C., preferably 1800° C. to 2200° C. in an oxygen containing atmosphere, to produce in the next stage polycrystalline or single crystals that can be used as scintillators.

Single crystals can be produced by the Czochralski method, the Bridgman technique, the Kyropoulos technique, and the Verneuil technique.

In the Czochralski method, the powder to be grown is melted under a controlled atmosphere in a suitable non-reacting container. By controlling the furnace temperature up to 2100° C. the material is melted. A seed crystal is lowered to contact the molten charge for nucleation. Then the nucleated seed is pulled away from the melt at a controlled rate. Crystals of large diameter can be grown using this method.

In the Bridgman (pulling method) technique, the material is melted in a vertical cylindrical container (called an ampoule), tapered conically with a point bottom. The container is lowered slowly from the hot zone of the furnace having a temperature up to 2100° C. into the cold zone. The rates of movement for such processes range from about 1-30 mm/hr. Crystallization begins at the tip and continues usually by growth from the first formed nucleus. Due to a directed and controlled cooling process of the cast, zones of aligned crystal lattices are created. In other words, a single crystal can be created.

In the Kyropoulos technique, the crystal is grown in a larger diameter than in the aforementioned two methods. As in the Czochralski method, here too a seed is brought into contact with the melt and is not raised much during the growth, i.e., part of the seed is allowed to melt and a short, narrow neck is grown. After this, the vertical motion of the seed is stopped and growth proceeds by decreasing the power into the melt.

In the Verneuil technique, (flame fusion) a fine dry powder of size 1 to 20 micrometers of the material to be grown is shaken through the wire mesh and allowed to fall through the oxy-hydrogen flame. The powder melts and a film of liquid is formed on the top of a seed crystal. This freezes progressively as the seed crystal is slowly lowered. The art of the method is to balance the rate of charge feed and the rate of lowering of the seed to maintain a constant growth rate and diameter.

In an embodiment, the rare earth oxyorthosilicate crystal is annealed in an oxygen containing environment at a temperature of 1200 to 1800° C. for a time period of 10 to 80 hours, where the oxygen containing environment has more than 1 percent of oxygen by weight.

The rare earth oxyorthosilicate crystals disclosed herein display increased light output over rare earth oxyorthosilicate crystals that do not contain multivalent cation substitutions. For example, rare earth oxyorthosilicate crystals that do not contain multivalent cation substitutions display a light output of less than 24,000 photons per MeV (ph/MeV), whereas rare earth oxyorthosilicate crystals that contain multivalent cation substitutions display light output of greater than 25,000 ph/MeV, preferably greater than 27,000 ph/MeV, preferably greater than 30,000 ph/MeV, preferably greater than 31,000 ph/MeV, preferably greater than 33,000 ph/MeV, and more preferably greater than 34,000 ph/MeV.

In an embodiment, the rare earth oxyorthosilicate crystals that contain the multivalent ion substitutions disclosed herein display a light decay of less than 35 nanoseconds, preferably less than 33 nanoseconds, and more preferably less than 30 nanoseconds. In contrast single crystals that do not contain multivalent cation substitutions have a decay time of greater than 42 nanoseconds.

In an embodiment, the rare earth oxyorthosilicate crystals that contain the multivalent cation substitutions disclosed herein display a percent energy resolution at 511 kiloelectron volts (keV) of 6.5 to 8.5%, preferably 6.75 to 7.50%. Rare earth oxyorthosilicate crystals that do not contain the multivalent cation substitutions disclosed herein display a percent energy resolution at 511 kiloelectron volts (keV) of greater than 9.4%.

The rare earth oxyorthosilicates disclosed herein are exemplified by the following non-limiting examples.

### EXAMPLES

### Example 1

This example was conducted to demonstrate the advantage of having multivalent ion (tetravalent, trivalent and divalent cations) substitutions in a rare earth oxyorthosilicate. Rare earth oxyorthosilicate crystals having a molar ratio of 10:1 of various trivalent cations (Y, Yb, Sc, Dy, and La) to the Ce³⁻ cation and two or more divalent cations (Mg and Ca) each having a molar ratio of 2:1 to the Ce³⁺ cation were prepared by the Czochralski method. The ratios specified above were in the melt state. The properties are shown in the Table 1 below.

TABLE 1

| | | | Decay | | En. Res | |
|---|---|---|---|---|---|---|
| Sample | Mol ratio in relation | CRT | Time | Abs. L.O | @511 keV | Afterglow |
| # | to Ce³⁺ in the melt | [ps] | [ns] | [ph/Mev] | [%] | (AMP, Time) |
| 1 | Gd 10:1, Mg 2:1, Ca 2:1 | 112 | 31.5-33.5 | 32200 | 7.1 | NO |
| 2 | Gd 10:1, Mg 2:1, Ca 2:1 | 117.6 | 34 | 33000 | 7.41 | YES Medium, |
| | | | | | | SLOW |
| 3 | Gd 10:1, Mg 2:1, Ca 2:1 | 115 | 33.64 | 33900- | 8.02-7.78 | YES High, |
| | | | | 33500 | | SLOW |
| 4 | Gd 10:1, Mg 2:1, Ca 2:1 | 109.55 | 31-32.7 | 32300- | 6.8-7.0 | YES Medium, |
| | | | | 33000 | | SLOW |
| 5 | Y 10:1, Ca 2:1, Mg 2:1 | 113.74 | 31.88 | 33800 | 7.31, 6.93 | YES High, |
| | | | | | | SLOW |
| 6 | Y 10:1, Ca 2:1, Mg 2:1 | 108 | 32.8 | 20700 | 6.67 | YES High, |
| | | | | | | SLOW |
| 7 | Yb 10:1, Ca 2:1, Mg 2:1 | 119 | 23.47 | 25400 | 10.17 | NO |
| 8 | Yb 10:1, Ca 2:1, Mg 2:1 | | 27.13 | 26000 | 9.7 | NO |
| 9 | Yb 10:1, Ca 2:1, Mg 2:1 | 115.5 | 28.53 | 32950- | 7.45 | NO |
| | | | | 34200 | | |
| 10 | Sc 10:1, Ca 2:1, Mg 2:1 | 106 | 31.8-32.7 | 32600 | 6.75 | YES High, |
| | | | | | | MEDIUM |
| 11 | Sc 10:1, Ca 2:1, Mg 2:1 | 114.58 | 33.37 | 30600- | 9.98 | YES Very |
| | | | | 31600 | | Low, |
| | | | | | | MEDIUM |
| 12 | Dy 10:1, Ca 2:1, Mg 2:1 | 111 | 30.6-31.6 | 31300 | 7.01-7.4 | YES Medium, |
| | | | | | | SLOW |
| 13 | Dy 10:1, Ca 2:1, Mg 2:1 | 111 | 31.9-31.4 | 33500 | 6.97-7.22 | YES Very |
| | | | | | | Low, |
| | | | | | | MEDIUM |
| 14 | La 10:1, Ca 2:1, Mg 2:1 | 112 | 30.63 | 34700 | 6.98 | Yest Medium |
| | | | | | | Low, FAST |
| 15 | La 10:1, Ca 2:1, Mg 2:1 | | 33.25 | 34700 | 7.14 | |
| 16 | La 10:1, Ca 2:1, Mg 2:1 | 112 | 33.69 | 34500 | 6.89 | YES High, |
| | | | | | | MEDIUM |
| 17 | La 10:1, Ca 2:1, Mg 2:1 | | 33.77 | 33500- | 8.39, 8.42 | |
| | | | | 34000 | | |
| 18 | La 10:1, Ca 2:1, Mg 2:1 | 111.12 | 32.4 | 32600 | 7.16 | |
| 19 | Ce4+ 1:1 | 117.42 | 33.5 | 30500 | 8.26 | |

Reference compositions co-doped with Ce³⁺ and without any multivalent ions show a coincidence resolving lime (CRT) of 160 picoseconds (ps), a decay lime of 42 nanoseconds (ns), light output (LO) of 25,000 ph/MeV, energy resolution (ER) of 9.7%, and high afterglow. In contrast, the rare earth oxyorthosilicate crystals (shown in Table 1) containing the multivalent ion substitutions display CRTs of 105 to 120 picoseconds and measured absolute light output.

### Example 2

This example demonstrates the linearity of the Samples A and B detailed below.

Sample A—multivalent composition of formula 1, having divalent cations substitution ratios Mg 2:1, Ca 2:1 relative to Ce³⁺ measured after thermal postprocessing.

Sample B—LSO Mg 0.25:1 ratio measured after thermal postprocessing.

Tables 2 and 3 show the linearity for Samples A and B respectively.

TABLE 2

| Energy | | Energy | | | | Absolute |
|---|---|---|---|---|---|---|
| Exci- | | Reso- | | | Lin- | LO per |
| tation | Photopeak | lution | Nphe* | NpheMeV* | earity | MeV |
| 32.10 | 24.8322 | 36.29 | 359.0 | 11186.0 | 0.97 | 29973.0 |
| 59.54 | 51.4356 | 23.74 | 744.0 | 12491.0 | 1.09 | 33471.0 |
| 122.06 | 104.7080 | 15.11 | 1514.0 | 12404.0 | 1.08 | 33237.0 |
| 511.00 | 430.0760 | 7.45 | 6219.0 | 12170.0 | 1.06 | 32609.0 |
| 661.66 | 525.5540 | 6.54 | 7599.0 | 11485.0 | 1.00 | 30775.0 |

*Nphe is the number of photoelectrons
*NpheMeV is the number of photoelectrons/MeV

TABLE 3

| Energy | | Energy | | | | Absolute |
|---|---|---|---|---|---|---|
| Exci- | | Reso- | | | Lin- | LO per |
| tation | Photopeak | lution | Nphe | NpheMeV | earity | MeV |
| 32.10 | 22.6758 | 38.40 | 328.0 | 10214.0 | 0.93 | 27370.0 |
| 59.54 | 48.9114 | 24.13 | 707.0 | 11878.0 | 1.08 | 31829.0 |
| 122.06 | 99.0805 | 16.47 | 1433.0 | 11737.0 | 1.07 | 31451.0 |
| 511.00 | 410.3400 | 8.05 | 5933.0 | 11611.0 | 1.06 | 31113.0 |
| 661.66 | 502.1540 | 7.72 | 7261.0 | 10974.0 | 1.00 | 29405.0 |

### Example 3

These examples show a variety of properties for the following compositions. Samples A, B and C presented in the following figures depict different compositions derived from formula (1) using different selected substitutions.

Sample A—Composition of formula (I) after thermal processing, whereby the divalent ion substitutions are molar ratios in relation to Ce³⁺ as follows: Mg 2:1, Ca 2:1 after annealing in an oxygen rich atmosphere.

Sample B—LSO 0.25:1 Composition of formula (1) after thermal processing, whereby the divalent ion substitution is a molar ratio in relation to Ce³⁺ as follows: Mg 0.25:1.

Sample C—Composition of formula (1) after thermal processing, whereby the divalent ion substitutions are molar ratios in relation to Ce³⁺ as follows: Mg 2:1, Ca 2:1 without thermal processing.

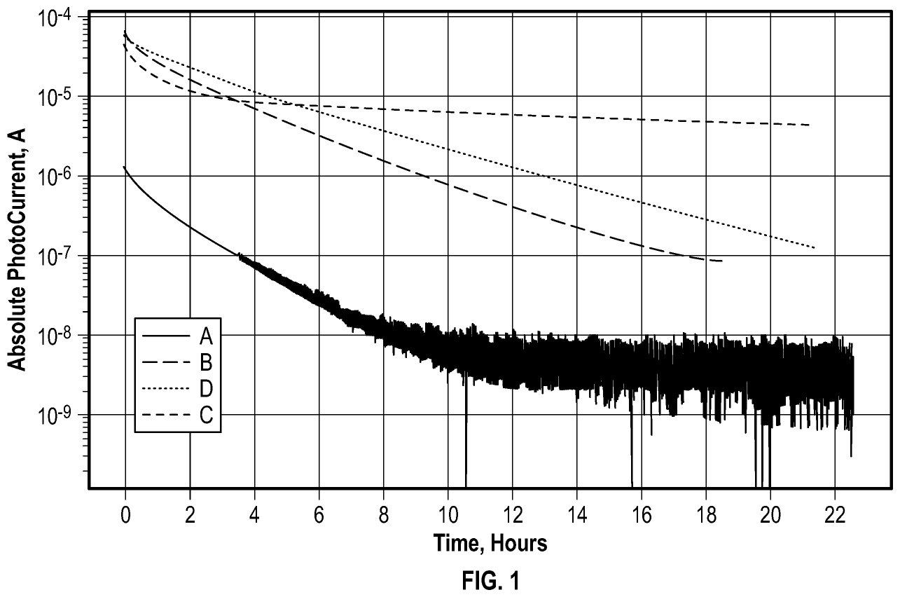

Sample D and “ref” are rare earth oxyorthosilicate materials with no additional multivalent ion substitutions. The properties of these rare earth oxyorthosilicates (Samples A, B, C, D and “ref”) are shown in the FIGS. 1-7.

FIG. 1 is a graph that depicts afterglow. Sample A which contains the multivalent substitutions and after thermal postprocessing shows the lowest afterglow.

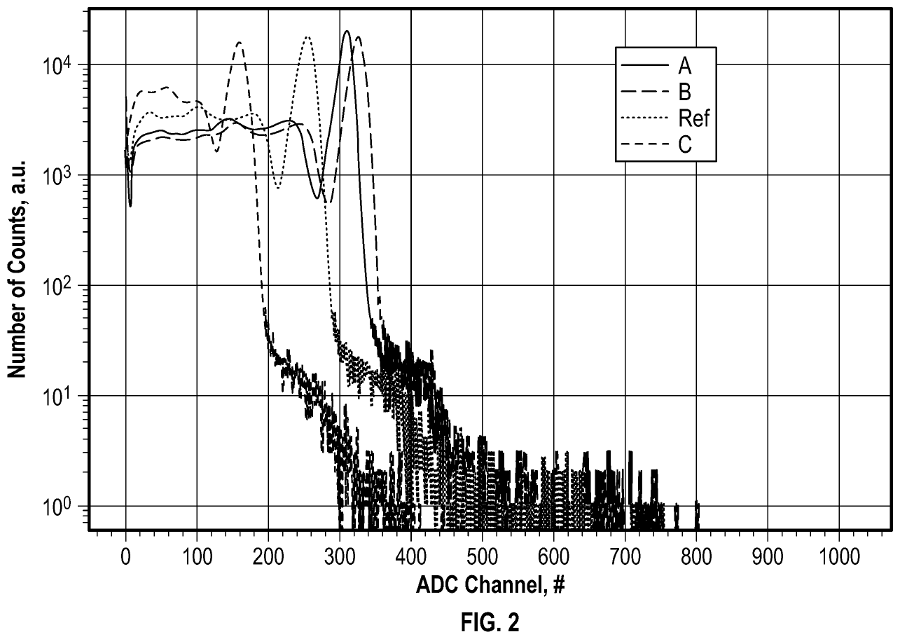

FIG. 2 is a graph that depicts energy spectra measured under 662 keV excitation. Sample B exhibits the best relative light output.

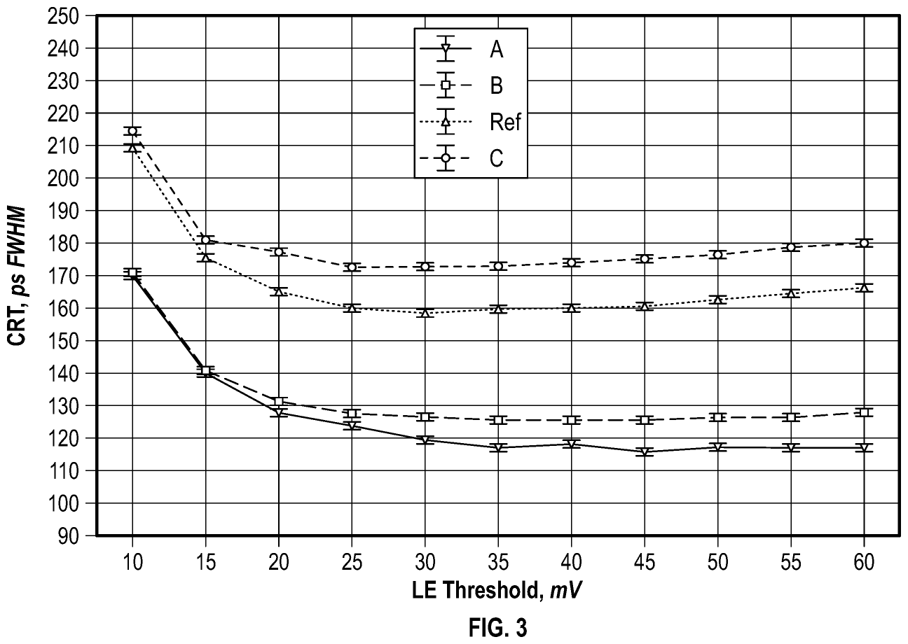

FIG. 3 depicts the coincidence resolving time for the various samples. Sample A exhibits the best relative CRT.

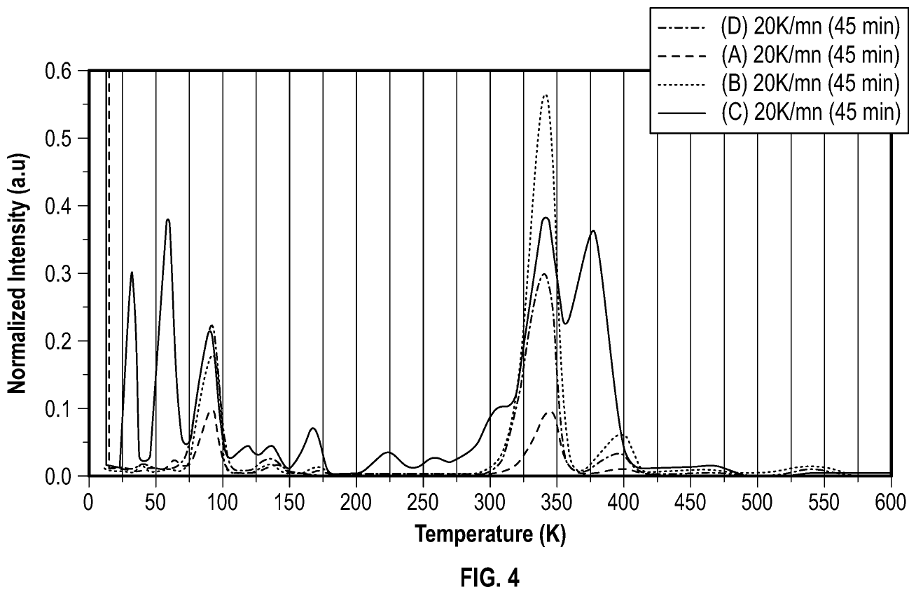

FIG. 4 exhibits that the relative concentration of oxygen vacancies (thermoluminescence peaks above 300 k). This concentration is significantly reduced in the case of sample A in comparison to sample D (standard reference).

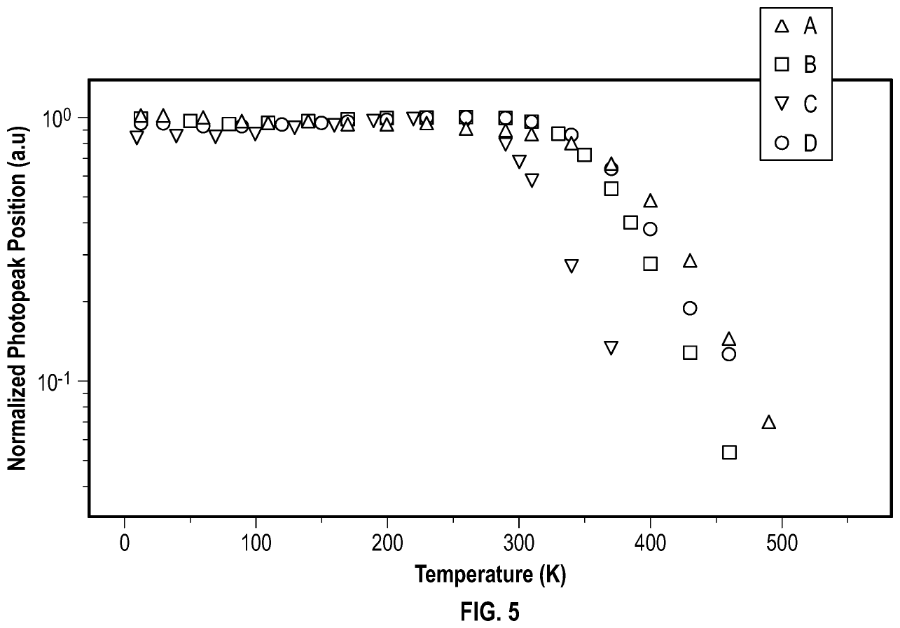

FIG. 5 depicts the thermal response of the compositions detailed above. Sample A has significantly better stability of light output at temperatures above 300K in comparison to sample C showing improvement in the performance of the material after thermal postgrowth processing.

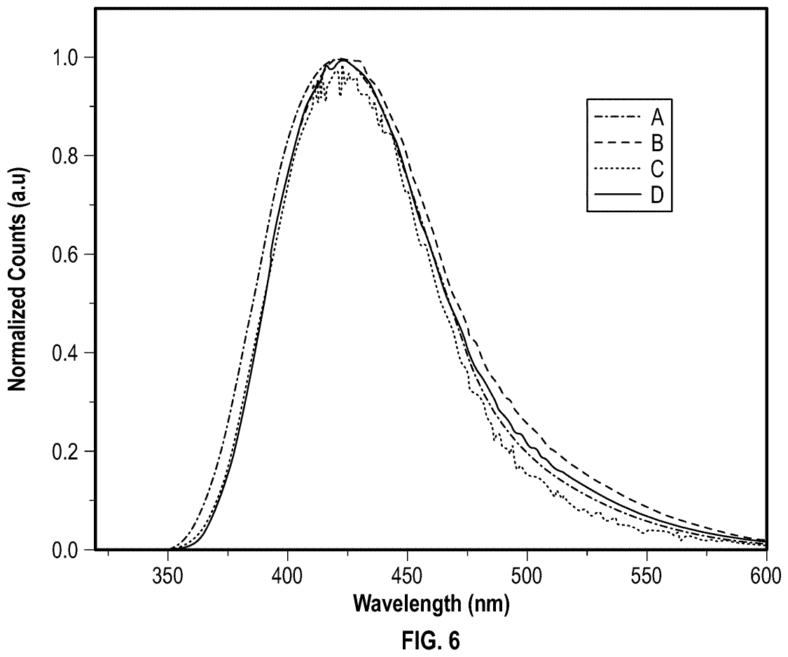

FIG. 6 depicts the radioluminescence of the selected compositions. Sample A shows a slight shift in UV range indicates increase in population of Ce1 site in relation to decreasing population of Ce2 site, in comparison to sample D (the comparative standard). This affect accounts for the shorter scintillation emission in the new compositions.

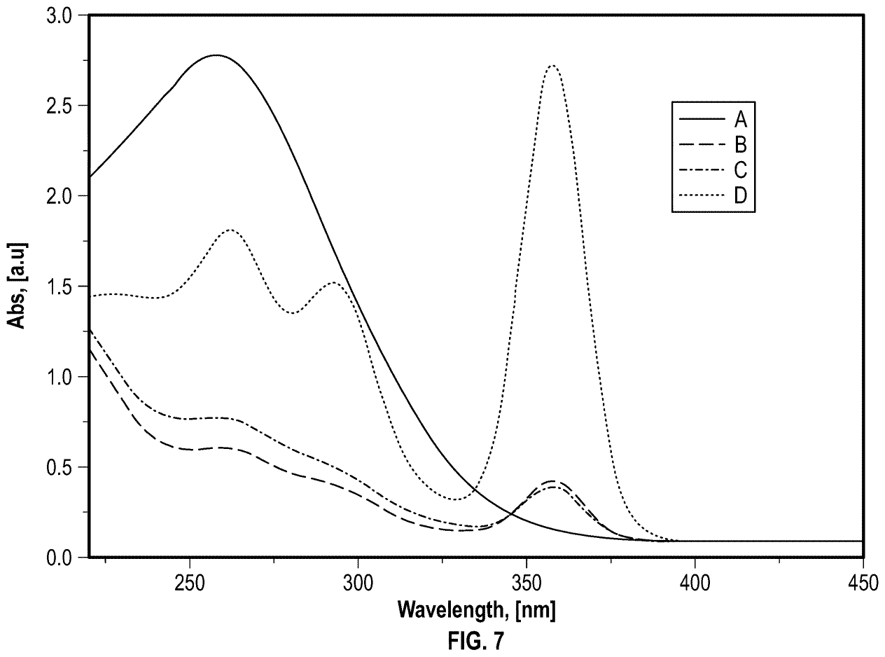

FIG. 7 depicts absorption of the material described by formula (1), with different levels trivalent and divalent substitutions ratio. Ce⁴⁺ in higher concentrations exhibit stronger charge transfer Ce⁴⁺ O²⁻ absorption within the range 220 nm to 350 nm.

While the invention has been described with reference to some embodiments, it will be understood by those skilled in the art that various changes may be made and equivalents may be substituted for elements thereof without departing from the scope of the invention. In addition, many modifications may be made to adapt a particular situation or material to the teachings of the invention without departing from essential scope thereof. Therefore, it is intended that the invention not be limited to the particular embodiments disclosed as the best mode contemplated for carrying out this invention, but that the invention will include all embodiments falling within the scope of the appended claims.

What is claimed is:

1. A rare earth oxyorthosilicate scintillator composition having a formula (1) 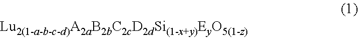
wherein Lu is lutetium; A comprises a trivalent ionic substitution selected from La, Ce, Pr, Nd, Sm, Eu, Gd, Tb, Dy, Ho, Er, Tm, Yb, Sc, Y, Al, Ga, B, In, Bi, Sb, Au, Rh, or a combination thereof; B comprises a non-trivalent ionic substitution selected from Mg, Ca, Sr, Ba, Li, Na, K, Rb, Mn, Cu, Zn, or a combination thereof; C comprises an activating cation substitution selected from Ce³⁺, Ce⁴⁺, Pr³⁻, or a combination thereof; D comprises a monovalent halogen anion substitution selected from F, Cl, Br, or a combination thereof; E comprises a trivalent ion substitution selected from La, Sc, Y, Gd, Al, Ga, In, B, In, Bi, Sb, Au, Rh, or a combination thereof; a is present in an amount of 0.5≤a≥0; b is present in an amount of 0.5≤b≥0; c is present in an amount of 0.5≤c≥0.00001; d is present in an amount of 0.5≤d≥0; x is present in an amount of 0.05≤x≥0; y is present in the amount 0.05≤y≥0; z is present in an amount of 0.2≤z≥0; where the sum of a|b is always greater than 0; and where the sum of a|b+c+d is always less than 1; and wherein A and C cannot simultaneously be identical trivalent cations.

2. The scintillator of claim 1, where the values of each of a, b, c and dare not simultaneously equal to 0.25 or greater and where the value of the sum of a|b|c|d ranges from 0.00001 to 0.4.

3. The scintillator of claim 1, where A is selected from La, Ce, Pr, Nd, Sm, Eu, Gd, Tb, Dy, Ho, Er, Tm, Yb, Sc, Y, Al, Ga, B, In, or a combination thereof.

4. The scintillator of claim 3, where B is a monovalent or divalent cation selected from Mg, Ca, Sr, Ba, Na, K, Rb, Mn, Cu, Zn, or a combination thereof; and where D is an anion of F, Cl, Br, or a combination thereof.

5. The scintillator of claim 1, where if A is a trivalent cation of Ce (Ce³⁺), then C will be either a tetravalent cation of Ce (Ce⁴⁺) or a trivalent cation of Pr (Pr³⁺).

6. The scintillator of claim 1, where trivalent ions that are not the activating cation C cause a dimensional change in a crystal lattice.

7. The scintillator of claim 4, where when the activating cation C is initially Ce³⁺ changes its charge state from Ce³⁻ to Ce⁴⁺ when its nearest neighbor is the trivalent ionic substitution A and the non-trivalent ionic substitution B.

8. The scintillator of claim 1, where a mole ratio of trivalent ionic substitution A to the activating cation C is greater than 0.1:1 and wherein a mole ratio of non-trivalent ionic substitution B to the activating cation C is greater than 1:1.

9. The scintillator of claim 8, where a content of ionic substitution E is defined by x≥y.

10. The scintillator of claim 1, wherein a mole ratio of trivalent ionic substitution A to the activating cation substitution C is greater than 5:1 and wherein a mole ratio of non-trivalent ionic substitution B to the activating cation substitution C is greater than 2:1.

11. The scintillator of claim 1, wherein A comprises at least one trivalent cation and wherein B comprises at least two different non-trivalent cations in a crystal lattice.

12. The scintillator of claim 11, wherein the trivalent cation substitution A is selected from La³⁻, Pr³⁺, Ce³⁺, Nd³⁺, Sm³⁺, Eu³⁺, Gd³⁺, Tb³⁺, Dy³⁺, Ho³⁺, Er³⁺, Tm³⁺, Yb³⁻, Sc³⁻, Y³⁻, Al³⁺, Ga³⁺, B³⁺, In³⁺, Bi³⁻, Au³⁺, Sb³⁺, Rh³⁺ or a combination thereof in a mole ratio of at least 10:1 with respect to the activating cation substitution of C and wherein the non-trivalent cation substitution B is selected from Mg²⁻, Ca²⁺, Sr²⁺, Ba²⁺, Na¹⁺, K¹⁺, Rb¹⁺, Mn²⁻, Cu²⁺, Cu¹⁻, Zn²⁺, or a combination thereof each in a mole ratio of at least 2:1 with respect to the activating cation substitution C.

13. The scintillator of claim 1, where the scintillator produces a light output of greater than 25,000 ph/MeV.

14. The scintillator of claim 8, where the scintillator produces a light decay of less than 35 nanoseconds.

15. The scintillator of claim 8, where the scintillator produces a coincidence resolving time of less than 200 picoseconds.

16. The scintillator of claim 1, where the trivalent ion substitutions A and the divalent ion substitutions B change cerium doped rare earth oxyorthosilicate cerium ion distribution to predominantly occupy a Ce1 crystallographic site.

17. The scintillator of claim 8, where the trivalent ion substitution A and the divalent ion substitution B change cerium doped rare earth oxyorthosilicate cerium ion to a predominantly Ce⁴⁺ charge state.

18. A method of manufacturing a rare earth oxyorthosilicate scintillator comprising:
a mixture of raw materials, that in manufacturing process produce a composition of formula (1): 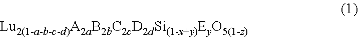
wherein Lu is lutetium; A comprises a trivalent ionic substitution selected from La, Ce, Pr, Nd, Sm, Eu, Gd, Tb, Dy, Ho, Er, Tm, Yb, Sc, Y, Al, Ga, B, In, Bi, Sb, Au, Rh, or a combination thereof; B comprises a non-trivalent ionic substitution selected from Mg, Ca, Sr, Ba, Li, Na, K, Rb, Mn, Cu, Zn, or a combination thereof; C comprises an activating cation substitution selected from Ce³⁺, Ce⁴⁺, Pr³⁻, or a combination thereof; D comprises a monovalent halogen anion selected from F, Cl, Br, or a combination thereof; E comprises a trivalent ion substitution selected from La, Sc, Y, Gd, Al, Ga, In, B, In, Bi, Sb, Au, Rh, or any combination of thereof; a is present in an amount of 0.5≤a≥0; b is present in an amount of 0.5≤b≥0; c is present in an amount of 0.5≤c≥0.00001; d is present in an amount of 0.5≤d≥0; x is present in an amount of 0.05≤x≥0; y is present in the amount 0.05≤y≥0; z is present in an amount of 0.2≤z≥0; where the sum of a+b is always greater than 0; and where the sum of a+b−c+d is always less than 1; and wherein A and C cannot simultaneously be identical trivalent cations;
melting the raw material in a crucible at a temperature of from 1500° C. to 2300° C.; and
pulling the crystal from the melt in an oxygen containing atmosphere using one of a Czochralski technique, a Bridgeman technique, a Kyropoulos technique and a Verneuil technique.

19. The method of claim 18, further comprising annealing the rare earth oxyorthosilicate scintillator in an oxygen containing environment at a temperature of 1200 to 1800° C. for a time period of 10 to 80 hours.

20. The method of claim 18, where a mole ratio of trivalent ionic substitution A to the activating cation substitution C is greater than 3:1 and wherein a mole ratio of non-trivalent ionic substitution B to the activating cation substitution C is greater than 1.5:1.

21. The method of claim 18, where a mole ratio of trivalent ionic substitution A to the activating cation substitution C is greater than 5:1 and wherein a mole ratio of non-trivalent ionic substitution B to the activating cation substitution C is greater than 2:1.

22. A radiation detector that uses the scintillator of claim 1.

23. The radiation detector of claim 22, used in positron emission tomography or in time-of-flight positron emission tomography.
